(19) United States
(12) Patent Application Publication
(10) Pub. No.: US 2024/0332890 A1
(43) Pub. Date: Oct. 3, 2024

(54) OPTICAL SEMICONDUCTOR DEVICE AND METHOD OF MANUFACTURING OPTICAL SEMICONDUCTOR DEVICE

(71) Applicants: SUMITOMO ELECTRIC INDUSTRIES, LTD., Osaka (JP); SUMITOMO ELECTRIC DEVICE INNOVATIONS, INC., Yokohama-shi (JP)

(72) Inventors: Daisuke INOUE, Osaka-shi (JP); Konosuke AOYAMA, Yokohama-shi (JP)

(73) Assignees: SUMITOMO ELECTRIC INDUSTRIES, LTD., Osaka (JP); SUMITOMO ELECTRIC DEVICE INNOVATIONS, INC., Yokohama-shi (JP)

(21) Appl. No.: 18/620,009

(22) Filed: Mar. 28, 2024

(30) Foreign Application Priority Data
Mar. 30, 2023 (JP) 2023-056179
Jul. 6, 2023 (JP) 2023-111493

(51) Int. Cl. H01S 5/02345; H01S 5/02325; H01S 5/12; H01S 5/50

(52) U.S. Cl. CPC H01S 5/02345; H01S 5/02325; H01S 5/12; H01S 5/50

(57) ABSTRACT

An optical semiconductor device includes, an optical amplifier portion configured to amplify a laser beam, a plurality of wiring pads for causing electric current to flow to the optical amplifier portion, and bonding wires. The optical amplifier portion includes a plurality of electrodes divided from each other in an optical axis direction. The number of the plurality of electrodes is greater than the number of the plurality of wiring pads. The bonding wires each connect a corresponding one of the plurality of electrodes to one of the plurality of wiring pads.

### CROSS REFERENCE TO RELATED APPLICATIONS

This application claims priority based on Japanese Patent Applications No. 2023-056179 filed on Mar. 30, 2023 and No. 2023-111493 filed on Jul. 6, 2023, and the entire contents of the Japanese patent applications are incorporated herein by reference.

### TECHNICAL FIELD

The present disclosure relates to an optical semiconductor device and a method of manufacturing an optical semiconductor device.

### BACKGROUND

An optical semiconductor device in which a semiconductor optical amplifier (SOA) is integrated in a semiconductor laser is known For example, refer to Non-PTL 1 (K. Carney et al., “Method to improve the noise figure and saturation power in multi-contact semiconductor optical amplifiers: Simulation and experiment”, Opt. Express, vol. 21, pp. 7180-7195 March 2013) and Non-PTL 2 (L. Hou, M. Haji, J. Akbar and J. Marsh, “Narrow linewidth laterally coupled 1.55 μm AlGaInAs/InP distributed feedback lasers integrated with a curved tapered semiconductor optical amplifier”, Opt. Lett., vol. 37, no. 21, pp. 4525-4527 November 2012). The optical semiconductor device described in Non-PTL 1 includes a semiconductor optical amplifier having three divided electrodes. The optical semiconductor device described in Non-PTL 2 includes a distributed feedback (DFB) laser. A region where a diffraction grating is formed in the DFB laser coincides with an electric current injection region.

### SUMMARY

An optical semiconductor device of the present disclosure includes an optical amplifier portion configured to amplify a laser beam, a plurality of wiring pads for causing electric current to flow to the optical amplifier portion, and bonding wires. The optical amplifier portion includes a plurality of electrodes divided from each other in an optical axis direction. The number of the plurality of electrodes is greater than the number of the plurality of wiring pads. The bonding wires each connect a corresponding one of the plurality of electrodes to one of the plurality of wiring pads.

### BRIEF DESCRIPTION OF THE DRAWINGS

FIG. 1 is a schematic view showing an optical semiconductor element according to an embodiment.

FIG. 2 is a cross-sectional view (part 1) showing an optical semiconductor element according to an embodiment.

FIG. 3 is a cross-sectional view (part 2) showing an optical semiconductor element according to an embodiment.

FIG. 4 is a cross-sectional view (part 3) showing an optical semiconductor element according to an embodiment.

FIG. 5 is a cross-sectional view (part 4) showing an optical semiconductor element according to an embodiment.

FIG. 6 is a schematic view showing an optical semiconductor device according to a first example of an embodiment.

FIG. 7 is a schematic view showing an optical semiconductor device according to a second example of an embodiment.

FIG. 8 is a flowchart showing a method of determining a driving condition of an optical semiconductor device.

FIG. 9 is a diagram (part 1) showing a step of determining a first electric current ratio.

FIG. 10 is a diagram (part 2) showing a step of determining a first electric current ratio.

FIG. 11 is a diagram (part 3) showing a step of determining a first electric current ratio.

FIG. 12 is a schematic diagram showing an optical semiconductor element used in an experiment.

FIG. 13 is a diagram showing a carrier density in an optical semiconductor element.

FIG. 14 is a diagram showing a photon density in an optical semiconductor element.

FIG. 15 is a diagram showing the relationship between the total electric current flowing through an optical amplifier portion, an optical output, and a power conversion efficiency.

FIG. 16 is a cross-sectional view showing an optical semiconductor element according to a modification of an embodiment.

FIG. 17 is a cross-sectional view (part 1) showing a method of manufacturing an optical semiconductor element according to a modification of an embodiment.

FIG. 18 is a cross-sectional view (part 2) showing a method of manufacturing an optical semiconductor element according to a modification of an embodiment.

FIG. 19 is a cross-sectional view (part 3) showing a method of manufacturing an optical semiconductor element according to a modification of an embodiment.

FIG. 20 is a cross-sectional view (part 4) showing a method of manufacturing an optical semiconductor element according to a modification of an embodiment.

FIG. 21 is a cross-sectional view (part 5) showing a method of manufacturing an optical semiconductor element according to a modification of an embodiment.

FIG. 22 is a cross-sectional view (part 6) showing a method of manufacturing an optical semiconductor element according to a modification of an embodiment.

FIG. 23 is a cross-sectional view (part 7) showing a method of manufacturing an optical semiconductor element according to a modification of an embodiment.

FIG. 24 is a cross-sectional view (part 8) showing a method of manufacturing an optical semiconductor element according to a modification of an embodiment.

FIG. 25 is a cross-sectional view (part 9) showing a method of manufacturing an optical semiconductor element according to a modification of an embodiment.

FIG. 26 is a cross-sectional view (part 10) showing a method of manufacturing an optical semiconductor element according to a modification of an embodiment.

FIG. 27 is a cross-sectional view (part 11) showing a method of manufacturing an optical semiconductor element according to a modification of an embodiment.

FIG. 28 is a cross-sectional view (part 12) showing a method of manufacturing an optical semiconductor element according to a modification of an embodiment.

FIG. 29 is a cross-sectional view (part 13) showing a method of manufacturing an optical semiconductor element according to a modification of an embodiment.

FIG. 30 is a cross-sectional view (part 14) showing a method of manufacturing an optical semiconductor element according to a modification of an embodiment.

FIG. 31 is a cross-sectional view (part 15) showing a method of manufacturing an optical semiconductor element according to a modification of an embodiment.

### DETAILED DESCRIPTION

In the conventional semiconductor optical amplifier, since the number of divisions and the length of the electrode are determined when designed, the number of electrodes driven at the same potential cannot be changed according to the purpose after an optical semiconductor element is completed.

An object of the present disclosure is to provide the optical semiconductor device capable of determining the number of electrodes driven at the same potential when the optical semiconductor element is mounted, and the method of manufacturing the optical semiconductor device.

Embodiments will be described below.

### DESCRIPTION OF EMBODIMENTS OF PRESENT DISCLOSURE

First, embodiments of the present disclosure will be listed and described. In the following description, the same or corresponding elements are denoted by the same reference numerals, and the same description thereof will not be repeated. Regarding crystallographic indications in the present disclosure, an individual orientation is represented by [ ], a group orientation is represented by < >, an individual plane is represented by ( ) and a group plane is represented by { }. Generally, a negative crystallographic index is supposed to be indicated by putting “-” (bar) above a numeral but is indicated by putting the negative sign before the numeral in the present disclosure. Also, when viewed from an arbitrary point, a side of the substrate may be referred to as over the substrate, an upper side of the substrate, or on the substrate, and a [−100] side of the substrate may be referred to as below the substrate, a lower side of the substrate, or under the substrate.

[1] An optical semiconductor device according to one aspect of the present disclosure includes an optical amplifier portion configured to amplify a laser beam, a plurality of wiring pads for causing electric current to flow to the optical amplifier portion, and bonding wires. The optical amplifier portion includes a plurality of electrodes divided from each other in an optical axis direction. The number of the plurality of electrodes is greater than the number of the plurality of wiring pads. The bonding wires each connect a corresponding one of the plurality of electrodes to one of the plurality of wiring pads. In this case, the number of electrodes driven at the same potential can be determined by changing the positions where the bonding wires are connected when the optical semiconductor element is mounted. Therefore, the same optical semiconductor element can be used in different driving methods.

[2] In [1], the plurality of electrodes may be divided from each other at equal intervals. In this case, it is easy to approximate an arbitrary distribution shape with high accuracy in an electric current distribution in an optical axis direction of the optical amplifier portion.

[3] In [1] or [2], lengths of the plurality of electrodes in the optical axis direction may be identical to each other. In this case, it is easy to approximate an arbitrary distribution shape with high accuracy in the electric current distribution in the optical axis direction of the optical amplifier portion.

[4] In [1] to [3], the optical semiconductor device may include a laser portion integrated with the optical amplifier portion and configured to emit the laser beam. In this case, a high optical output is easily obtained.

[5] In [4], the laser portion may be of a distributed feedback type. In this case, since the laser oscillates in a single mode, a laser can be easily used as a continuous light source for a data center.

[6] In [4], the laser portion may include a diffraction grating layer and a contact layer provided on the diffraction grating layer. The diffraction grating layer may include a first region in which constant-period diffraction gratings are formed in the optical axis direction and a second region in which the diffraction gratings are not formed. The first region may be positioned farther than the second region from the optical amplifier portion in the optical axis direction. In this case, the first region can be positioned far from the non-injection region where electric current is not injected.

[7] In [6], the contact layer may include a first end portion close to the optical amplifier portion in the optical axis direction. A boundary between the first region and the second region may be positioned farther than the first end portion from the optical amplifier portion in the optical axis direction. In this case, the first region can be positioned far from the non-injection region where electric current is not injected. In the non-injection region, the efficiency is reduced by light absorption. By positioning the first region away from the non-injection region, light passes through the non-injection region only once, and light absorption in the non-injection region can be reduced.

[8] In [7], a distance between the boundary and the first end portion in the optical axis direction may be 5 μm to 10 μm. When the distance is 5 μm or more, the optical semiconductor element is hardly affected by misalignment in manufacturing the optical semiconductor element. When the distance is 10 μm or less, the characteristics of the optical semiconductor element are less likely to be affected.

[9] In [4], the laser portion and the optical amplifier portion each may include a semiconductor layer, a contact layer provided on the semiconductor layer, a contact electrode provided on the contact layer, and an electrically insulating film provided on the contact electrode. The contact layer and the contact electrode may be divided between the laser portion and the optical amplifier portion by a separation groove. The separation groove may be covered by the electrically insulating film. In this case, high moisture resistance is obtained.

In [1], the optical amplifier portion may include a semiconductor layer, a contact layer provided on the semiconductor layer, a contact electrode provided on the contact layer, and an electrically insulating film provided on the contact electrode. The contact layer and the contact electrode may be divided in the optical axis direction into a plurality of contact layers and a plurality of contact electrodes by a separation groove. The separation groove may be covered by the electrically insulating film. In this case, high moisture resistance is obtained.

In [9] or [10], a width of the separation groove at an interface between the semiconductor layer and the contact layer may be 5 μm to 10 μm. When the width is 5 μm or more, high insulation properties are easily secured between the adjacent contact layers. When the width is 10 μm or less, light absorption in the semiconductor layer is easily reduced.

A method of manufacturing an optical semiconductor device according to another aspect of the present disclosure includes preparing an optical semiconductor element, the optical semiconductor element including a laser portion configured to emit a laser beam and an optical amplifier portion configured to amplify the laser beam, preparing a submount provided with a plurality of wiring pads for causing electric current to flow to the optical amplifier portion, and mounting the optical semiconductor element on the submount. The optical amplifier portion includes a plurality of electrodes divided from each other in an optical axis direction. The number of the plurality of electrodes is greater than The number of the plurality of wiring pads. The mounting includes connecting each of the plurality of electrodes by a corresponding one of bonding wires to one of the plurality of wiring pads. In this case, the number of electrodes driven at the same potential can be determined by changing the positions where the bonding wires are connected when the optical semiconductor element is mounted. Therefore, the same optical semiconductor element can be used in different driving methods.

In [12], the mounting may include determining, in accordance with a target value of an optical output of the optical semiconductor element, positions to which the bonding wires is connected. In this case, the power conversion efficiency can be increased for each target optical output.

### DETAILS OF EMBODIMENTS OF PRESENT DISCLOSURE

Hereinafter, embodiments of the present disclosure will be described in detail, but the present disclosure is not limited thereto.

### [Optical Semiconductor Element]

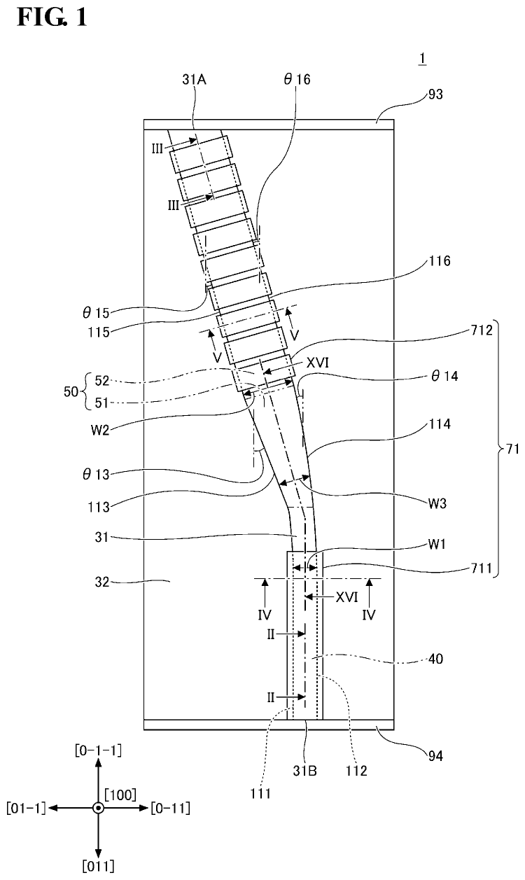

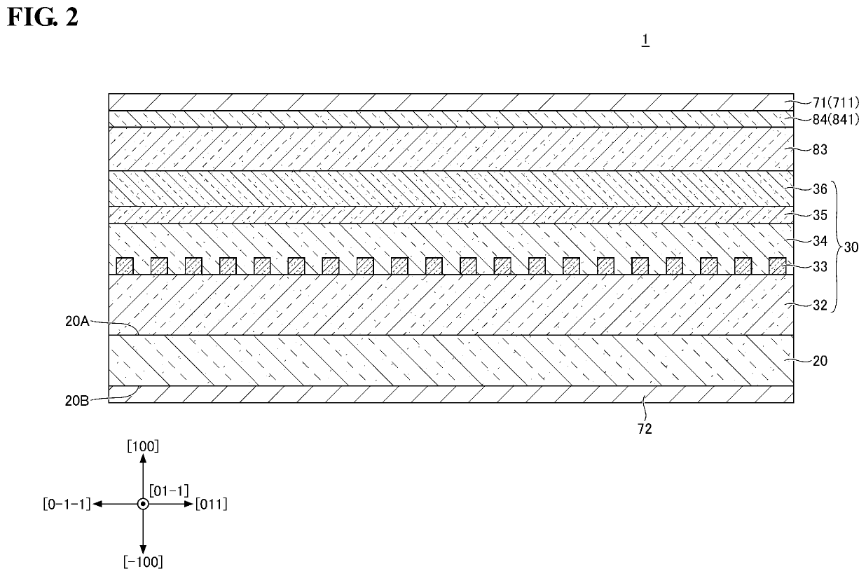

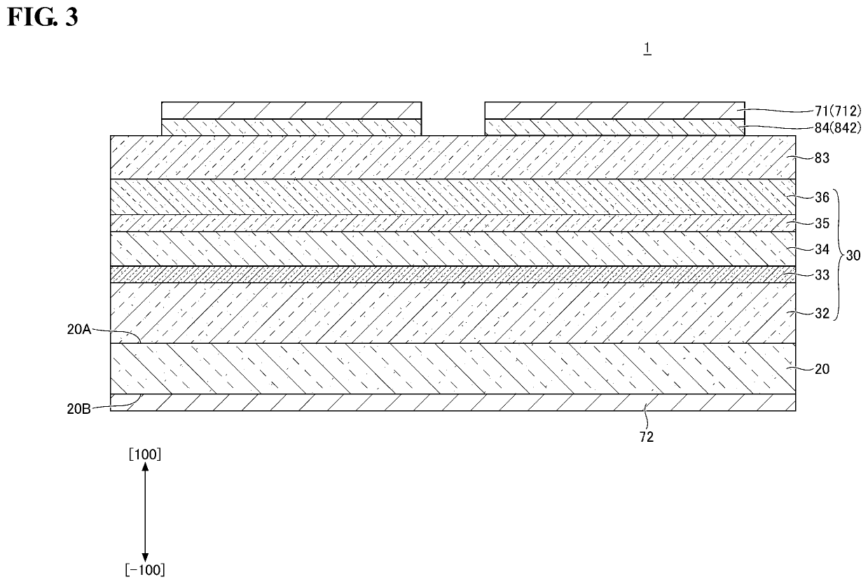

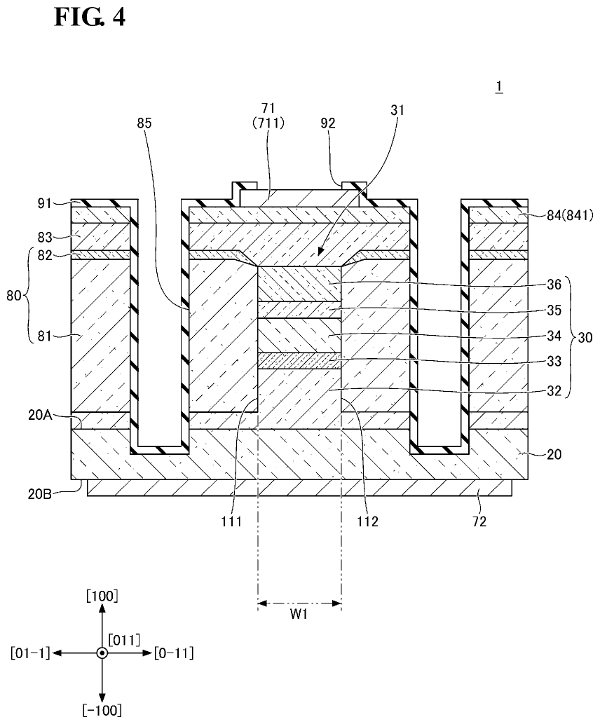

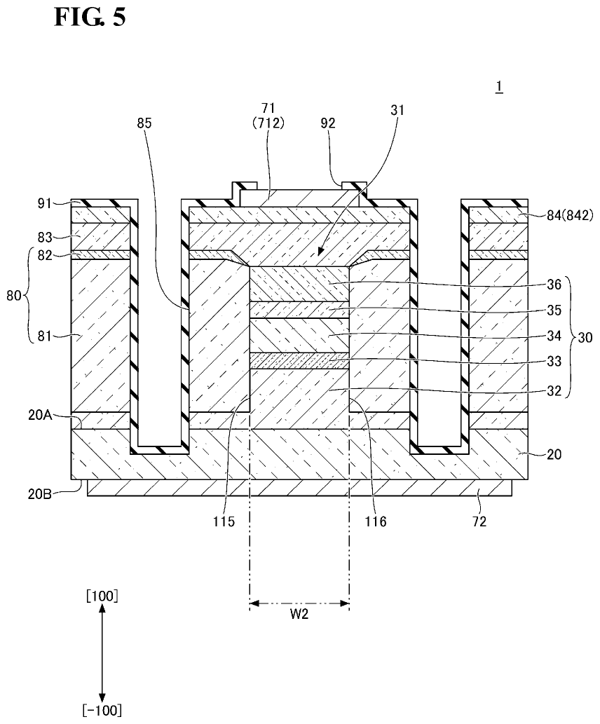

Referring to FIGS. 1 to 5, an optical semiconductor element 1 according to an embodiment will be described. FIG. 1 is a schematic view showing optical semiconductor element 1 according to the embodiment. FIGS. 2 to 5 are cross-sectional views showing optical semiconductor element 1 according to the embodiment. FIG. 1 shows a divided structure of an upper electrode 712 in a plan view. FIG. 2 corresponds to a cross-sectional view along the line II-II in FIG. 1. FIG. 3 corresponds to a cross-sectional view along the line III-III in FIG. 1. FIG. 4 corresponds to a cross-sectional view along the line IV-IV in FIG. 1. FIG. 5 corresponds to a cross-sectional view along the line V-V in FIG. 1.

Optical semiconductor element 1 mainly includes a substrate 20, a semiconductor layer 30, and a semiconductor layer 80.

Substrate 20 is, for example, an n-type indium phosphide (InP) substrate. Substrate 20 has a first major surface 20A and a second major surface 20B opposite to first major surface 20A. Substrate 20 is doped with silicon (Si) or sulfur(S) at a concentration of 1.0×10¹⁸ cm⁻³, for example. A plane orientation of first major surface 20A is (100), and a plane orientation of second major surface 20B is (−100).

Semiconductor layer 30 is provided on first major surface 20A. Semiconductor layer 30 has a buffer layer 32, a diffraction grating layer 33, an n-type cladding layer 34, an active layer 35, and a p-type cladding layer 36.

Buffer layer 32 is provided on substrate 20. Buffer layer 32 is, for example, an n-type InP layer having a thickness of about 500 nm. Buffer layer 32 is doped with Si at a concentration of 5.0×10¹⁷ cm⁻³, for example. Buffer layer 32 inherits the crystal orientation of substrate 20.

Diffraction grating layer 33 is provided on buffer layer 32. Diffraction grating layer 33 is, for example, an n-type gallium indium arsenide phosphide (GaInAsP) layer having a thickness of about 50 nm. A bandgap wavelength λg of diffraction grating layer 33 at room temperature is about 1.15 μm. Diffraction grating layer 33 is doped with Si at a concentration of 5.0×10¹⁷ cm⁻³, for example. Diffraction grating layer 33 inherits the crystal orientation of buffer layer 32.

N-type cladding layer 34 is provided on diffraction grating layer 33 and buffer layer 32. N-type cladding layer 34 covers diffraction grating layer 33. N-type cladding layer 34 is, for example, an n-type InP layer having a thickness of about 500 nm. N-type cladding layer 34 is doped with Si at a concentration of 5.0×10¹⁷ cm⁻³, for example. N-type cladding layer 34 inherits the crystal orientations of diffraction grating layer 33 and buffer layer 32.

Active layer 35 is provided on n-type cladding layer 34. Active layer 35 has a quantum well layer and two barrier layers sandwiching the quantum well layer therebetween. The quantum well layer is, for example, a GaInAsP layer or an aluminum gallium indium arsenide (AlGaInAs) layer having a thickness of about 80 nm. Each of the barrier layers is, for example, a GaInAsP layer or an AlGaInAs layer having a thickness of about 30 nm. The bandgap wavelength λg of the barrier layer at room temperature is about 1.15 μm. Active layer 35 inherits the crystal orientation of n-type cladding layer 34.

P-type cladding layer 36 is provided on active layer 35. P-type cladding layer 36 is, for example, a p-type InP layer having a thickness of about 200 nm. P-type cladding layer 36 is doped with zinc (Zn) at a concentration of 5.0×10¹⁷ cm⁻³, for example. P-type cladding layer 36 inherits the crystal orientation of active layer 35.

Semiconductor layer 30 inherits the crystal orientation of substrate 20. The crystal orientation in the following description is the crystal orientation of substrate 20. A mesa 31 is formed in semiconductor layer 30. Mesa 31 is formed so that a part of buffer layer 32 is exposed from mesa 31. Mesa 31 has a height of about 1000 nm, for example. Mesa 31 includes a laser portion 40 and an optical amplifier portion 50. As will be described in detail later, as shown in FIG. 1, laser portion 40 extends substantially parallel to a [0-1-1] direction, and optical amplifier portion 50 extends substantially parallel to a direction that is inclined from the [0-1-1] direction toward a [01-1] direction by 6° to 8°. Optical amplifier portion 50 is connected to an end portion of the [0-1-1] side of laser portion 40. Laser portion 40 and optical amplifier portion 50 are integrated. In this case, a high optical output is easily obtained. A dimension of laser portion 40 in the direction parallel to the [0-1-1] direction is 350 μm to 1500 μm, for example. A dimension of optical amplifier portion 50 in the direction parallel to the [0-1-1] direction is 500 μm to 1800 μm, for example.

Laser portion 40 has a first surface 111 and a second surface 112 perpendicular to first major surface 20A. A plane orientation of first surface 111 is (01-1), and a plane orientation of second surface 112 is (0-11). That is, first surface 111 and second surface 112 are parallel to a {01-1} plane. A first distance W1 between first surface 111 and second surface 112 is 1.5 μm to 2.5 μm, for example.

Optical amplifier portion 50 has a taper portion 51 and a parallel portion 52. Taper portion 51 is connected to an end portion of laser portion 40 on the [0-1-1] side of laser portion 40, and parallel portion 52 is connected to an end portion of taper portion 51 opposite to laser portion 40.

Taper portion 51 has a third surface 113 and a fourth surface 114 perpendicular to first major surface 20A. Third surface 113 is continuous with first surface 111, and fourth surface 114 is continuous with second surface 112. Third surface 113 and fourth surface 114 are respectively inclined from a (01-1) plane and a (0-11) plane in the same direction, in a plane parallel to first major surface 20A. The direction in which third surface 113 and fourth surface 114 are inclined is a direction parallel to a (100) plane. The inclination from the (01-1) plane of third surface 113 is more than the inclination from the (0-11) plane of fourth surface 114. That is, third surface 113 is inclined more than fourth surface 114 from the {01-1} plane, in a plane parallel to first major surface 20A. Therefore, a third distance W3 between third surface 113 and fourth surface 114 gradually increases as the distance from laser portion 40 increases. The magnitude of the angle formed by third surface 113 and the (01-1) plane is an angle θ13, the magnitude of the angle formed by fourth surface 114 and the (0-11) plane is an angle θ14, and angle θ13 is larger than angle θ14. In the present disclosure, the magnitude of the angle formed by two planes is 0° to 90°. The magnitude of the angle formed by two planes can be measured, for example, through microscopic observation.

Parallel portion 52 has a fifth surface 115 and a sixth surface 116 perpendicular to first major surface 20A. Fifth surface 115 and sixth surface 116 are parallel to each other. A second distance W2 between fifth surface 115 and sixth surface 116 is greater than first distance W1. From a reverse perspective, first distance W1 is smaller than second distance W2. Second distance W2 is, for example, 2.0 μm to 10 μm. Fifth surface 115 and sixth surface 116 are respectively inclined from the (01-1) plane and the (0-11) plane in a direction identical to the directions in which third surface 113 and fourth surface 114 are inclined, in a plane parallel to first major surface 20A. For example, in a plane parallel to first main surface 20A, fifth surface 115 and sixth surface 116 are respectively inclined at 6° to 8° from the (01-1) plane and the (0-11) plane in a direction identical to the directions in which third surface 113 and fourth surface 114 are inclined. The magnitude of the angle formed by fifth surface 115 and the (01-1) plane is an angle θ15, the magnitude of the angle formed by sixth surface 116 and the (0-11) plane is an angle θ16, and angle θ15 and angle θ16 are equal to each other and are, for example, 6° to 8°.

In the embodiment, third surface 113 and fifth surface 115 are inclined such that the normal vectors point between the [01-1] direction and a direction, and fourth surface 114 and sixth surface 116 are inclined such that the normal vectors point between a [0-11] direction and the [0-1-1] direction.

Fifth surface 115 is inclined less than third surface 113 from the (01-1) plane, in a plane parallel to first major surface 20A. From a reverse perspective, third surface 113 is inclined more than fifth surface 115 from the (01-1) plane, in a plane parallel to first major surface 20A. For example, third surface 113 is inclined from the (01-1) plane more than fifth surface 115 by an angle larger than 0° and smaller than or equal to 1°, in a plane parallel to first major surface 20A. Angle θ13 is larger than angle θ15, and for example, the difference between angle θ13 and angle θ15 is larger than 0° and smaller than or equal to 1°.

Sixth surface 116 is inclined more than fourth surface 114 from the (0-11) plane, in a plane parallel to first major surface 20A. From a reverse perspective, fourth surface 114 is inclined less than sixth surface 116 from the (0-11) plane, in a plane parallel to first major surface 20A. For example, fourth surface 114 is inclined from the (0-11) plane less by an angle larger than 0° and smaller than or equal to 1° than sixth surface 116, in a plane parallel to first major surface 20A. Angle θ16 is larger than angle θ14, and for example, the difference between angle θ16 and angle θ14 is larger than 0° and smaller than or equal to 1º.

For example, the difference between angle θ13 and angle θ15 is equal to the difference between angle θ16 and angle θ14, and at the boundary between taper portion 51 and parallel portion 52, the optical axis of taper portion 51 and the optical axis of parallel portion 52 are connected to each other and are parallel to each other. The optical axis of parallel portion 52 is inclined at 6° to 8° from the [0-1-1] direction, for example.

As shown in FIG. 2, in laser portion 40, constant-period diffraction gratings are formed in diffraction grating layer 33. On the other hand, as shown in FIG. 3, in optical amplifier portion 50, diffraction grating layer 33 is not formed with diffraction gratings, and the entire upper surface of buffer layer 32 is covered with diffraction grating layer 33 in mesa 31.

Semiconductor layer 80 is provided on both side of mesa 31 so as to bury mesa 31. Semiconductor layer 80 has a p-type blocking layer 81 and an n-type blocking layer 82. Semiconductor layer 80 is in contact with first surface 111, second surface 112, third surface 113, fourth surface 114, fifth surface 115, and sixth surface 116. At least a portion of the upper surface of p-type cladding layer 36 is exposed from semiconductor layer 80.

P-type blocking layer 81 is provided on buffer layer 32. P-type blocking layer 81 is in contact with first surface 111, second surface 112, third surface 113, fourth surface 114, fifth surface 115, and sixth surface 116. P-type blocking layer 81 is in contact with each side surface of buffer layer 32, diffraction grating layer 33, n-type cladding layer 34, active layer 35, and p-type cladding layer 36. P-type blocking layer 81 is, for example, a p-type InP layer whose thickness of the thickest portion is 1000 nm to 1500 nm. P-type blocking layer 81 is doped with Zn at a concentration of, for example, 1.0×10¹⁷ cm⁻³ to 1.0×10¹⁸ cm⁻³. Chlorine (Cl) may be added to a part of p-type blocking layer 81.

N-type blocking layer 82 is provided on p-type blocking layer 81. N-type blocking layer 82 is, for example, an n-type InP layer whose thickness of the thickest portion is 300 nm to 500 nm. N-type blocking layer 82 is doped with Si at a concentration of, for example, about 5.0×10¹⁸ cm⁻³. Cl may be added to a part of n-type blocking layer 82.

Optical semiconductor element 1 further includes a p-type semiconductor layer 83, a contact layer 84, an upper electrode 71, a lower electrode 72, an electrically insulating film 91, an anti-reflection film 93, and a high-reflection film 94.

P-type semiconductor layer 83 is provided on p-type cladding layer 36 and n-type blocking layer 82. P-type semiconductor layer 83 is, for example, a p-type InP layer whose thickness of the thickest portion is 2500 nm to 3500 nm. P-type semiconductor layer 83 is doped with Zn at a concentration of, for example, 1.0×10¹⁸ cm⁻³ to 2.0×10¹⁸ cm⁻³. P-type semiconductor layer 83 can function as a part of p-type cladding layer 36.

Contact layer 84 is provided on p-type semiconductor layer 83. Contact layer 84 includes a p-type GaInAsP layer and a p-type indium gallium arsenide (InGaAs) layer. The GaInAsP layer is provided on p-type semiconductor layer 83. For example, the GaInAsP layer has a thickness of about 200 nm and is doped with Zn at a concentration of about 2.0×10¹⁸ cm⁻³. The InGaAs layer is provided on the GaInAsP layer. For example, the InGaAs layer has a thickness of about 300 nm and is doped with Zn at a concentration of about 8.0×10¹⁸ cm⁻³. The band gap of contact layer 84 is smaller than the band gap of p-type semiconductor layer 83.

Upper electrode 71 is provided on contact layer 84. Upper electrode 71 is provided so as to overlap mesa 31 in a plan view. For example, the contour of mesa 31 is inside the contour of upper electrode 71 in a plan view.

Contact layer 84 and upper electrode 71 are divided between laser portion 40 and optical amplifier portion 50. Contact layer 84 and upper electrode 71 are insulated and separated between laser portion 40 and optical amplifier portion 50. Electric currents can be independently supplied to laser portion 40 and optical amplifier portion 50.

Contact layer 84 includes a contact layer 841 and a contact layer 842. Contact layer 841 is provided in laser portion 40. Contact layer 842 is provided in optical amplifier portion 50. Contact layer 842 is divided into a plurality of (for example, nine) parts along the optical axis direction of parallel portion 52. The plurality of the parts of contact layer 842 are insulated and separated from each other. Contact layer 842 may be divided into parts with equal intervals. Lengths of the plurality of the parts of contact layers 842 may be identical to length of parallel portion 52 in the optical axis direction.

Upper electrode 71 includes an upper electrode 711 and upper electrode 712. Upper electrode 711 is provided in laser portion 40. Upper electrode 712 is provided in optical amplifier portion 50. Upper electrode 712 is divided into a plurality of (for example, nine) parts along the optical axis direction of parallel portion 52. The plurality of the parts of upper electrodes 712 are insulated and separated from each other. In this case, electric currents can be independently supplied to each of the plurality of the parts of upper electrodes 712. Lengths of the plurality of the parts of upper electrodes 712 may be identical to length of parallel portion 52 in the optical axis direction. In this case, it is easy to approximate an arbitrary distribution shape with high accuracy in the electric current distribution in the optical axis direction of optical amplifier portion 50. Upper electrodes 712 may be divided into parts with equal intervals. That is, lengths of the plurality of the parts of upper electrodes 712 may be identical to length of parallel portion 52 in the optical axis direction, and the distance between the adjacent parts of upper electrodes 712 may be the same. In this case, it is easy to approximate an arbitrary distribution shape with high accuracy in the electric current distribution in the optical axis direction of optical amplifier portion 50.

A Trench 85 is formed in a stacked body of substrate 20, buffer layer 32, semiconductor layer 80, p-type semiconductor layer 83, and contact layer 84. Trench 85 is formed on a [01-1] side and a [0-11] side of mesa 31 so as to put mesa 31 in between. Trench 85 extends along mesa 31, for example.

Electrically insulating film 91 covers the upper surface of contact layer 84, the upper surface and the side surface of upper electrode 71, and the inner wall surface and the bottom surface of trench 85. Electrically insulating film 91 is, for example, a silicon-oxide (SiO₂) film, a silicon-oxynitride (SiON) film, or a silicon-nitride (SiN) film. An opening portion 92 is formed in electrically insulating film 91 to expose a portion of the upper surface of upper electrode 71.

Lower electrode 72 is provided on second major surface 20B of substrate 20. Lower electrode 72 is in contact with substrate 20.

Mesa 31 has a first end surface 31A having a plane orientation of (0-1-1) and a second end surface 31B having a plane orientation of (011). Anti-reflection film 93 covers first end surface 31A, and high-reflection film 94 covers second end surface 31B. For example, anti-reflection film 93 includes a titanium dioxide (TiO₂) or tantalum dioxide (Ta₂O₃) as a high-refractive index film, and a silicon oxide (SiO₂) or an aluminum oxide (Al₂O₃) as a low-refractive index film, and the low-refractive index film is between first end surface 31A and the high-refractive index film. For example, high-reflection film 94 includes a titanium dioxide (TiO₂) or tantalum dioxide (Ta₂O₃) as a high-refractive index film, and a silicone oxide (SiO₂) or an aluminum oxide (Al₂O₃) as a low-refractive index film, and has a multilayered structure. In the multilayered structure, a structure in which the low-refractive index film is between second end surface 31B and the high-refractive index film is repeated for two periods to five periods.

In optical semiconductor element 1, a portion including laser portion 40 of mesa 31 in a plan view functions as a distributed feedback (DFB) laser. In this case, since the laser oscillates in a single mode, the laser can be easily used as a continuous light source for a data center. In optical semiconductor element 1, a portion including optical amplifier portion 50 of mesa 31 in plan view functions as a semiconductor optical amplifier.

### [Optical Semiconductor Device]

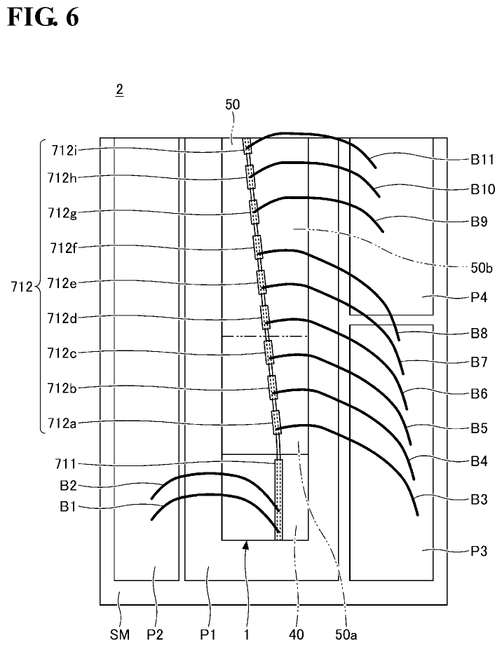

Referring to FIG. 6, an optical semiconductor device 2 according to a first example of an embodiment will be described. FIG. 6 is a schematic view showing optical semiconductor device 2 according to the first example of the embodiment.

Optical semiconductor device 2 includes optical semiconductor element 1, a submount SM, wiring pads P1 to P4, and bonding wires B1 to B11.

Submount SM is formed of, for example, aluminum nitride (AlN).

Wiring pads P1, P2, P3, and P4 are provided on submount SM. Wiring pads P1, P2, P3, and P4 are insulated and separated from each other. A constant electric current source is connected to wiring pads P1, P2, P3, and P4. Wiring pads P1, P2, P3, and P4 are formed of, for example, copper.

Optical semiconductor element 1 is mounted on submount SM. Optical semiconductor element 1 is fixed on wiring pad P1 by a bonding material such as solder or a conductive adhesive. In optical semiconductor element 1, lower electrode 72 is electrically connected to wiring pad P1. In optical semiconductor element 1, upper electrode 711 is wire-connected to wiring pad P2, and upper electrode 712 is wire-connected to wiring pads P3 and P4.

Bonding wires B1 and B2 are electrically connected to upper electrode 711 and wiring pad P2. Bonding wires B3, B4, B5, B6, B7, and B8 electrically connect upper electrodes 712a, 712b, 712c, 712d, 712e, and 712f to wiring pad P3. Bonding wires B9, B10, and B11 electrically connect upper electrodes 712g, 712h, and 712i to wiring pad P4.

Optical semiconductor device 2 has nine upper electrodes 712a to 712i and two wiring pads P3 and P4 provided in optical amplifier portion 50. Six upper electrodes 712a, 712b, 712c, 712d, 712e, and 712f are wire-connected to wiring pad P3, and three upper electrodes 712g, 712h, and 712i are wire-connected to wiring pad P4. In this case, six upper electrodes 712a, 712b, 712c, 712d, 712e, and 712f have the same potential, and three upper electrodes 712g, 712h, and 712i have the same potential. Therefore, in optical semiconductor device 2, one optical amplifier portion 50 functions as two optical amplifier portions 50a and 50b provided along the optical axis direction. Optical amplifier portions 50a and 50b are provided in this order from laser portion 40. For example, when upper electrode 712a to upper electrode 712i are divided at equal intervals along the optical axis direction and the lengths in the optical axis direction are identical to each other, the ratio of the length of optical amplifier portion 50a to the length of optical amplifier portion 50b is 2:1.

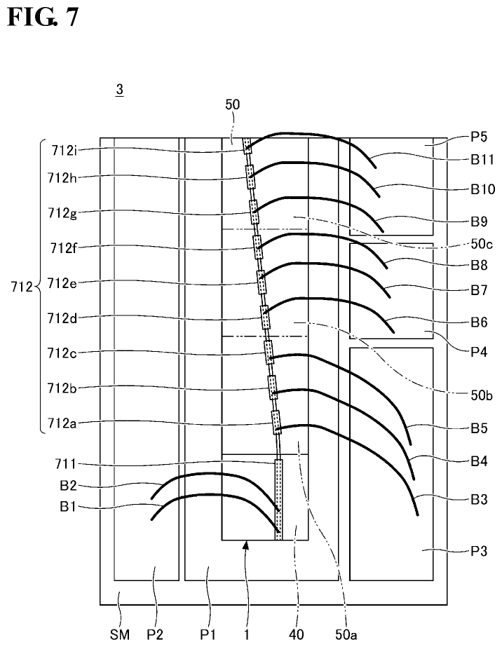

Referring to FIG. 7, an optical semiconductor device 3 according to a second example of an embodiment will be described. FIG. 7 is a schematic view showing optical semiconductor device 3 according to the second example of the embodiment.

Optical semiconductor device 3 is different from optical semiconductor device 2 in that the number of wiring pads wire-connected to upper electrode 712 is three. Optical semiconductor device 3 includes optical semiconductor element 1, submount SM, wiring pads P1 to P5, and bonding wires B1 to B11.

Submount SM is formed of, for example, AlN.

Wiring pads P1, P2, P3, P4, and P5 are provided on submount SM. Wiring pads P1, P2, P3, P4, and P5 are insulated and separated from each other. A constant electric current source is connected to wiring pads P1, P2, P3, P4, and P5. Wiring pads P1, P2, P3, P4, and P5 are formed of, for example, copper.

Optical semiconductor element 1 is mounted on submount SM. Optical semiconductor element 1 is fixed on wiring pad P1 by a bonding material such as solder or a conductive adhesive. In optical semiconductor element 1, lower electrode 72 is electrically connected to wiring pad P1. In optical semiconductor element 1, upper electrode 711 is wire-connected to wiring pad P2, and upper electrode 712 is wire-connected to wiring pads P3, P4, and P5.

Bonding wires B1 and B2 are electrically connected to upper electrode 711 and wiring pad P2. Bonding wires B3, B4, and B5 electrically connect upper electrodes 712a, 712b, and 712c to wiring pad P3. Bonding wires B6, B7, and B8 electrically connect upper electrodes 712d, 712e, and 712f to wiring pad P4. Bonding wires B9, B10, and B11 electrically connect upper electrodes 712g, 712h, and 712i to wiring pad P5.

Optical semiconductor device 3 has nine upper electrodes 712a to 712i and three wiring pads P3, P4, and P5 provided in optical amplifier portion 50. Three upper electrodes 712a, 712b, and 712c are wire-connected to wiring pad P3, three upper electrodes 712d, 712e, and 712f are wire-connected to wiring pad P4, and three upper electrodes 712g, 712h, and 712i are wire-connected to wiring pad P5. In this case, three upper electrodes 712a, 712b, and 712c have the same potential, three upper electrodes 712d, 712e, and 712f have the same potential, and three upper electrodes 712g, 712h, and 712i have the same potential. Therefore, in optical semiconductor device 3, one optical amplifier portion 50 functions as three optical amplifier portions 50a, 50b, and 50c provided along the optical axis direction. Optical amplifier portions 50a, 50b, and 50c are provided in this order from laser portion 40. For example, when upper electrode 712a to upper electrode 712i are divided at equal intervals along the optical axis direction and the lengths in the optical axis direction are identical to each other, the ratio of the length of optical amplifier portion 50a, the length of optical amplifier portion 50b, and the length of optical amplifier portion 50c is 1:1:1.

As described above, optical semiconductor devices 2 and 3 each have the plurality of upper electrodes 712, the number of which is more than the number of wiring pads. In this case, the number of upper electrodes 712 driven at the same potential can be determined by changing the positions where the bonding wires are connected when optical semiconductor element 1 is mounted. Therefore, same optical semiconductor element 1 can be used in different driving methods.

### [Manufacturing Method of Optical Semiconductor Device]

A manufacturing method of optical semiconductor device 2 will be described. Optical semiconductor device 2 can be manufactured by the following method. Optical semiconductor device 3 can be manufactured by the same method as optical semiconductor device 2.

First, optical semiconductor element 1 and submount SM are prepared (hereinafter referred to as “preparation process”). The preparation process includes preparing optical semiconductor element 1 having laser portion 40 and optical amplifier portion 50. The preparation process includes preparing submount SM provided with a plurality of wiring pads P1, P2, P3, and P4.

Next, optical semiconductor element 1 is mounted on submount SM (hereinafter referred to as “mounting process”). The mounting process includes fixing optical semiconductor element 1 onto wiring pad P1 provided on submount SM by a bonding material such as solder or a conductive adhesive, and electrically connecting lower electrode 72 and wiring pad P1. The mounting process includes connecting upper electrode 711 and wiring pad P2 by bonding wires B1 and B2. The mounting process includes connecting each of the plurality of upper electrodes 712a, 712b, 712c, 712d, 712e, 712f, 712g, 712h, 712i by a corresponding one of bonding wires to one of the plurality of wiring pads P3, P4. In this case, the number of electrodes driven at the same potential can be determined by changing the positions where the bonding wires are connected when optical semiconductor element 1 is mounted. Therefore, same optical semiconductor element 1 can be used in different driving methods. The mounting process may include determining, in accordance with a target value of an optical output of optical semiconductor element 1, positions to which the bonding wires is connected. In this case, the power conversion efficiency can be increased for each target optical output. In the embodiment, the mounting process includes connecting upper electrodes 712a, 712b, 712c, 712d, 712e, 712f and wiring pad P3 by bonding wires B3, B4, B5, B6, B7, and B8. In the embodiment, the mounting process includes connecting upper electrodes 712g, 712h, 712i and wiring pad P4 by bonding wires B9, B10, B11.

### [Method of Determining Driving Condition of Optical Semiconductor Device]

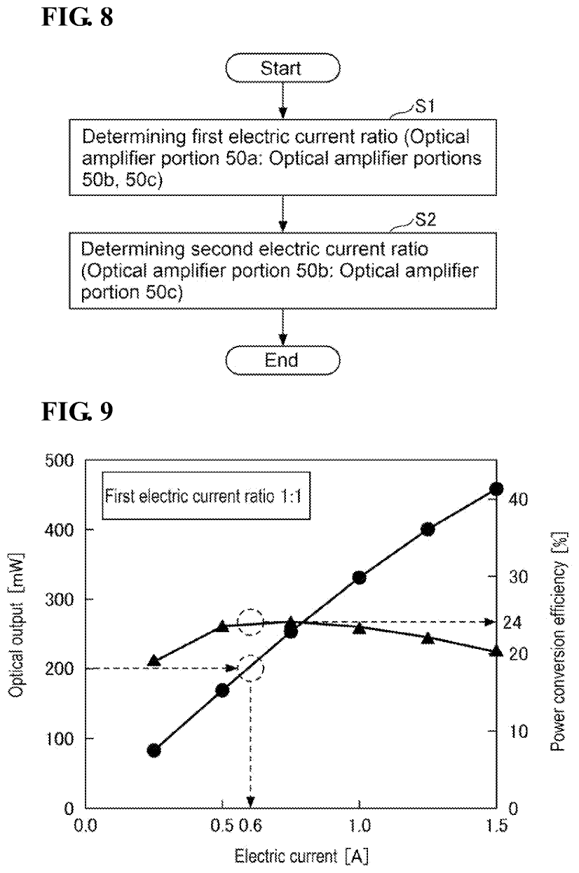

A method of determining the driving condition of optical semiconductor device 3 will be described with reference to FIGS. 8 to 11. In the embodiment, a case where the target value of the optical output of optical semiconductor element 1 is 200 mW will be described as an example. FIG. 8 is a flowchart showing a method of determining a driving condition of optical semiconductor device 3.

As shown in FIG. 8, the method of determining the driving condition of optical semiconductor device 3 includes steps S1 and S2. The step S1 is a step of determining the ratio of the electric current flowing through optical amplifier portion 50a and the total electric current flowing through optical amplifier portions 50b and 50c (hereinafter, referred to as a “first electric current ratio”). The step S2 is a step of determining the ratio of the electric current flowing through optical amplifier portion 50b and the electric current flowing through optical amplifier portion 50c (hereinafter, referred to as a “second electric current ratio”).

In the step S1, first, in a state where the first electric current ratio is 1:1, an electric current is supplied to laser portion 40 to emit a laser beam, and the optical output and power conversion efficiency of optical semiconductor element 1 are measured while changing the total electric current supplied to optical amplifier portions 50a, 50b, and 50c. Thus, a first relation information indicating the relation between the total electric current flowing through optical amplifier portions 50a, 50b, and 50c and the optical output and the power conversion efficiency of optical semiconductor element 1 in the case where the first electric current ratio is 1:1 is generated. An example of the first relation information is shown in FIG. 9.

FIG. 9 is a diagram showing a step of determining a first electric current ratio. FIG. 9 is a diagram showing the relationship between the total electric current flowing through optical amplifier portions 50a, 50b, and 50c and the optical output and power conversion efficiency (PCE) of optical semiconductor element 1 when the first electric current ratio is 1:1. In FIG. 9, the horizontal axis represents the total electric current [A] flowing through optical amplifier portions 50a, 50b, and 50c, the left vertical axis represents the optical output [mW] of optical semiconductor element 1, and the right vertical axis represents the power conversion efficiency [%] of optical semiconductor element 1. In FIG. 9, circles represent optical output and triangles represent power conversion efficiency.

Next, based on the first relation information, the total electric current flowing through optical amplifier portions 50a, 50b, and 50c, which is necessary to obtain the target value of the optical output, is obtained. As shown in FIG. 9, the total electric current flowing through optical amplifier portions 50a, 50b, and 50c required to obtain 200 mW, which is the target value of the optical output, is 0.6A, and the power conversion efficiency is 24%.

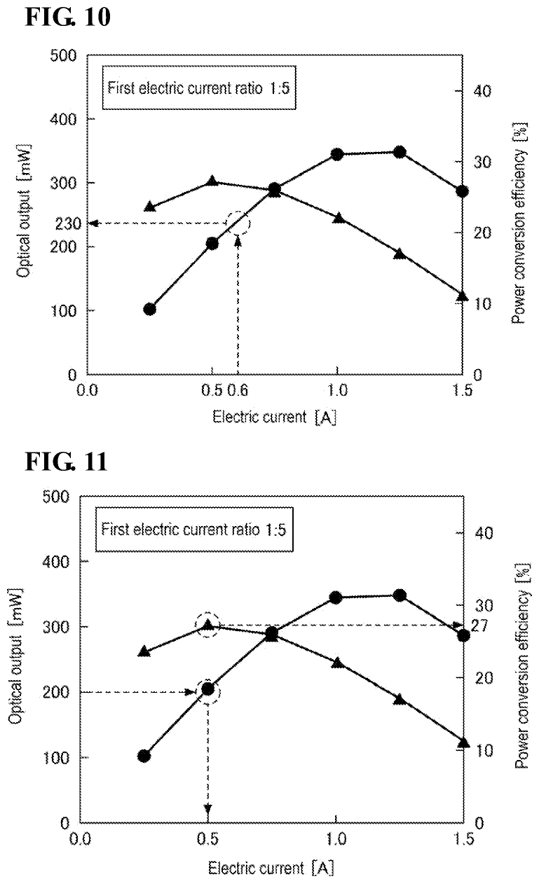

Next, in a state where the first electric current ratio is changed to 1:5, an electric current is supplied to laser portion 40 to emit a laser beam, and the optical outputs and the power conversion efficiency of optical semiconductor element 1 are measured, while changing the total current supplied to optical amplifier portions 50a, 50b, and 50c. Thus, a second relation information indicating the relation between the total electric current flowing through optical amplifier portions 50a, 50b, and 50c and the optical output and the power conversion efficiency of optical semiconductor element 1 in the case where the first electric current ratio is 1:5 is generated. An example of the second relation information is shown in FIGS. 10 and 11.

FIGS. 10 and 11 are diagrams showing the steps of determining the first electric current ratio. FIGS. 10 and 11 are diagrams showing the relationship between the total electric current flowing through optical amplifier portions 50a, 50b, and 50c and the optical output and power conversion efficiency of optical semiconductor element 1 when the first electric current ratio is 1:5. In FIGS. 10 and 11, the horizontal axis represents the total electric current [A] flowing through optical amplifier portions 50a, 50b, and 50c, the left vertical axis represents the optical output [mW] of optical semiconductor element 1, and the right vertical axis represents the power conversion efficiency [%] of optical semiconductor element 1. In FIGS. 10 and 11, circles represent optical output and triangles represent power conversion efficiency.

Next, based on the second relation information, the optical output of optical semiconductor element 1 in the case where the total electric current flowing through optical amplifier portions 50a, 50b, and 50c is 0.6A is obtained. As shown in FIG. 10, when the total electric current flowing through optical amplifier portions 50a, 50b, and 50c is 0.6A, the optical output of optical semiconductor element 1 is 230 mW.

Next, in the case where the first electric current ratio is 1:5, the total electric current flowing through optical amplifier portions 50a, 50b, and 50c, which is necessary to obtain the target value of the optical output, is obtained. As shown in FIG. 11, the total electric current flowing through optical amplifier portions 50a, 50b, and 50c required to obtain 200 mW, which is the target value of the optical output, is 0.5A, and the power conversion efficiency is 27%. That is, by changing the first electric current ratio from 1:1 to 1:5, the power conversion efficiency when optical semiconductor element 1 is driven by the output of 200 mW is improved from 24% to 27%.

Next, in a state where the first electric current ratio is changed to another ratio, the power conversion efficiency is obtained by the same procedure as the method shown in FIGS. 10 and 11, and the procedure is repeated until the power conversion efficiency converges, and the first electric current ratio in the case where the maximum power conversion efficiency is obtained is determined, and the step S1 is finished.

In the step S2, the second electric current ratio is determined by the same method as the method of determining the first electric current ratio.

By the steps S1 and S2, the power conversion efficiency can be optimized when optical semiconductor element 1 is driven by the optical output of 200 mW.

In the embodiment, the case where the power conversion efficiency is optimized when optical semiconductor element 1 is driven by the optical output of 200 mW has been described as an example, but the present invention is not limited thereto. The power conversion efficiency can be optimized in the same manner even when optical semiconductor element 1 is driven by an optical output other than 200 mW.

In the embodiment, optical amplifier portion 50 includes three optical amplifier portions 50a, 50b, and 50c, but the present invention is not limited thereto. For example, even when optical amplifier portion 50 includes two optical amplifier portions or when optical amplifier portion 50 includes four or more optical amplifier portions, the power conversion efficiency of optical semiconductor element 1 can be optimized in the same manner.

### [Experimental Results]

The results of experiments using optical semiconductor element 1 according to the embodiment will be described.

### (Carrier Density and Photon Density)

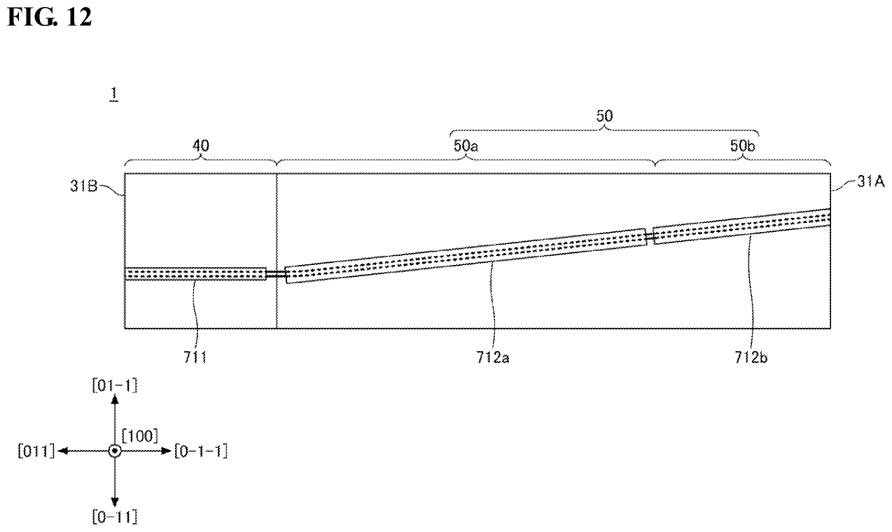

First, optical semiconductor element 1 according to the embodiment was prepared. FIG. 12 is a schematic diagram showing optical semiconductor element 1 used in the experiments. As shown in FIG. 12, optical semiconductor element 1 includes laser portion 40 and optical amplifier portion 50. Laser portion 40 is provided with upper electrode 711. Optical amplifier portion 50 is provided with two divided upper electrodes 712a and 712b. Optical amplifier portion 50 includes optical amplifier portion 50a provided with upper electrode 712a and optical amplifier portion 50b provided with upper electrode 712b.

Next, an electric current is supplied to laser portion 40 to emit a laser beam, and the carrier density and the photon density in optical semiconductor element 1 were measured while supplying an electric current to optical amplifier portions 50a and 50b. The ratio of the electric current flowing through optical amplifier portion 50a to the electric current flowing through optical amplifier portion 50b (hereinafter referred to as “electric current ratio”) was set to 1:3 or 1:1.

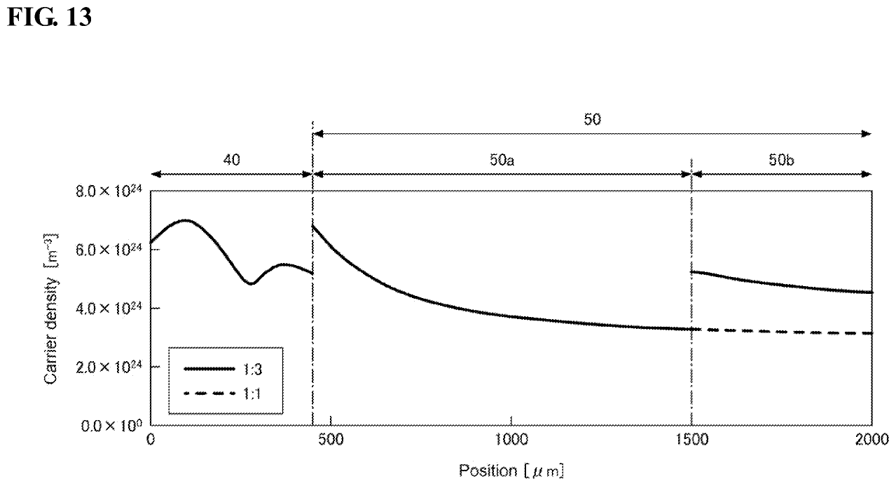

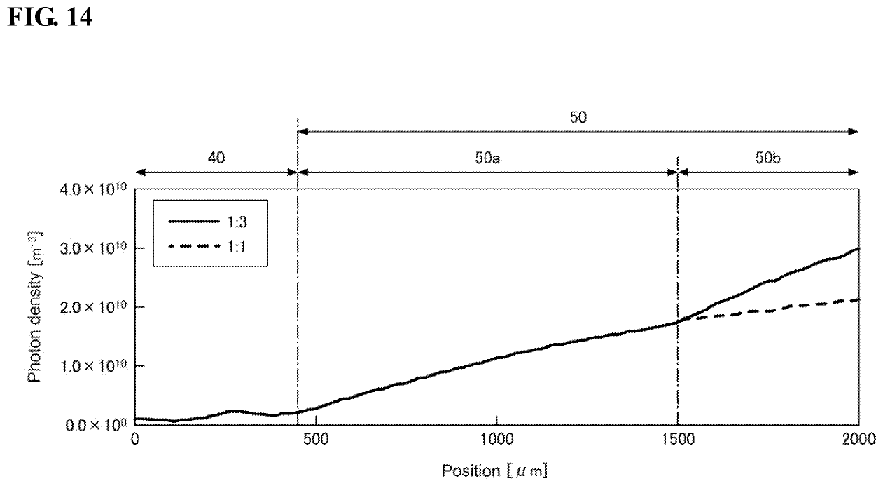

FIG. 13 is a diagram showing a carrier density in optical semiconductor element 1. FIG. 14 is a diagram showing a photon density in optical semiconductor element 1. The horizontal axis in FIGS. 13 and 14 represents the position [μm] of optical semiconductor element 1. The position of optical semiconductor element 1 is a position [μm] along a direction parallel to the [0-1-1] direction from second end surface 31B to first end surface 31A. The vertical axis in FIG. 13 indicates the carrier density [m⁻³] of optical semiconductor element 1, and the vertical axis in FIG. 14 indicates the photon density [m⁻³] of optical semiconductor element 1. In FIGS. 13 and 14, the solid line indicates the case where the electric current ratio is 1:3, and the dashed line indicates the case where the electric current ratio is 1:1.

As shown in FIGS. 13 and 14, it is understood that the carrier density and the photon density in optical amplifier portion 50b are higher when the electric current ratio is 1:3 than when the electric current ratio is 1:1. This result shows that the laser beam can be amplified in optical amplifier portion 50b by supplying the electric current to optical amplifier portion 50b larger than the electric current flowing through optical amplifier portion 50a. On the other hand, this result shows that the photon density in optical amplifier portion 50b is saturated, and the laser beam can hardly be amplified when the same electric current is supplied to optical amplifier portions 50a and 50b.

### (Optical Output and Power Conversion Efficiency)

First, optical semiconductor element 1 shown in FIG. 12 was prepared. Next, an electric current is supplied to laser portion 40 to emit a laser beam, and the optical output and power conversion efficiency of optical semiconductor element 1 were measured while changing the total electric current supplied to optical amplifier portions 50a and 50b. The electric current ratio was set to 1:4 or 1:1.

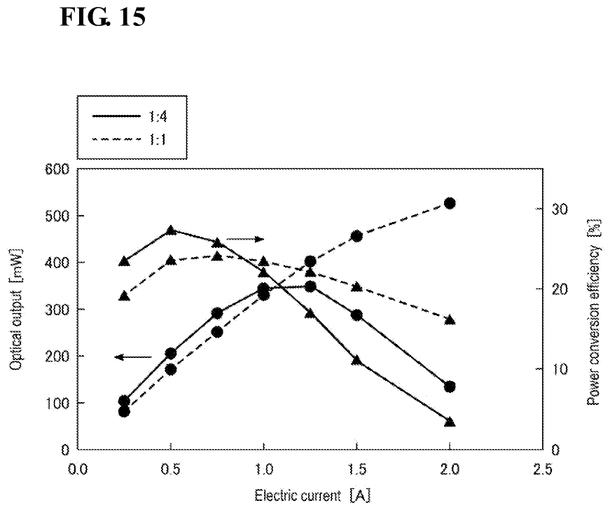

FIG. 15 is a diagram showing the relationship between the total electric current flowing through optical amplifier portions 50a and 50b, and an optical output and a power conversion efficiency. In FIG. 15, the horizontal axis represents the total electric current [A] flowing through optical amplifier portions 50a and 50b, the left vertical axis represents the optical output [mW] of optical semiconductor element 1, and the right vertical axis represents the power conversion efficiency [%] of optical semiconductor element 1. In FIG. 15, circles represent the optical output and triangles represent power conversion efficiency. In FIG. 15, the solid line indicates the case where the electric current ratio is 1:4, and the dashed line indicates the case where the electric current ratio is 1:1.

As shown in FIG. 15, it is understood that the relationship between the total electric current flowing through optical amplifier portions 50a and 50b and the optical output and power conversion efficiency of optical semiconductor element 1 is changed by changing the electric current ratio. For example, power conversion efficiency can be improved at low optical output (for example, 150 mW or less) when electric current ratio is 1:4, and high optical output (for example, more than 500 mW) is obtained when electric current ratio is 1:1. That is, in same optical semiconductor element 1, the power conversion efficiency at a low optical output (for example, 150 mW or less) can be improved while a high optical output (for example, more than 500 mW) is possible. As described above, according to optical semiconductor element 1 in which the plurality of divided upper electrodes 712 are provided, the power conversion efficiency can be optimized according to the target value of the optical output.

On the other hand, when upper electrode 712 is not divided but is one electrode, the relationship between the electric current flowing through optical amplifier portion 50 and the optical output and power conversion efficiency of optical semiconductor element 1 does not change. Therefore, it is difficult to optimize the power conversion efficiency of optical semiconductor element 1 in accordance with the target value of the optical output.

### [Modification of Optical Semiconductor Element]

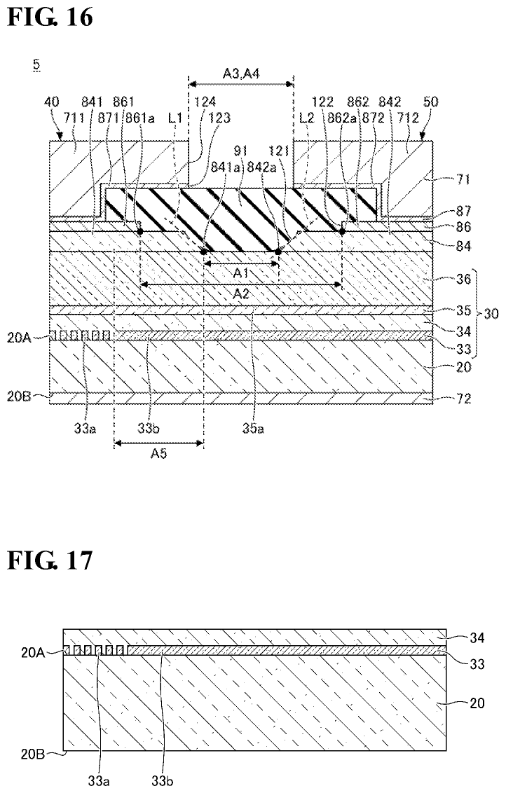

Referring to FIG. 16, an optical semiconductor element 5 according to a modification of the embodiment will be described. FIG. 16 is a cross-sectional view showing optical semiconductor element 5 according to the modification of the embodiment. FIG. 16 corresponds to a cross-sectional view along the line XVI-XVI in FIG. 1. Hereinafter, the configuration different from optical semiconductor element 1 according to the embodiment will be mainly described.

Optical semiconductor element 5 includes substrate 20, semiconductor layer 30, contact layer 84, a contact electrode 86, electrically insulating film 91, an underlying metal film 87, upper electrode 71, and lower electrode 72.

Substrate 20 is, for example, an n-type InP substrate. Substrate 20 has first major surface 20A and second major surface 20B opposite to first major surface 20A.

Semiconductor layer 30 is provided on first major surface 20A. Semiconductor layer 30 has diffraction grating layer 33, n-type cladding layer 34, active layer 35, and p-type cladding layer 36. Diffraction grating layer 33 is, for example, a GaInAsP layer. N-type cladding layer 34 is, for example, an n-type InP layer. Active layer 35 has a quantum well layer and two barrier layers sandwiching the quantum well layer therebetween. The quantum well layer is, for example, a GaInAsP layer. The barrier layer is, for example, a GaInAsP layer. P-type cladding layer 36 is, for example, a p-type InP layer.

Contact layer 84 is provided on semiconductor layer 30. Contact layer 84 has a p-type GaInAsP layer and a p-type InGaAs layer. The GaInAsP layer is provided on p-type cladding layer 36. The InGaAs layer is provided on the GaInAsP layer.

Contact layer 84 includes contact layer 841 and contact layer 842. Contact layer 841 is provided in laser portion 40. Contact layer 842 is provided in optical amplifier portion 50. Contact layer 841 and contact layer 842 are divided by a first separation groove 121. Contact layer 841 and contact layer 842 are insulated and separated from each other.

Contact layer 841 has a first end portion 841a. First end portion 841a is a position where a tangential line L1 at a position corresponding to half the thickness of contact layer 841 in the side surface of first separation groove 121 of contact layer 841 and the upper surface of p-type cladding layer 36 intersect.

Contact layer 842 has a second end portion 842a. Second end portion 842a is a position where a tangential line L2 at a position corresponding to half the thickness of contact layer 842 in the side surface of first separation groove 121 of contact layer 842 and the upper surface of p-type cladding layer 36 intersect.

A width A1 of first separation groove 121 may be 5 μm to 10 μm. When the width is 5 μm or more, high insulation properties are easily secured between contact layer 841 and contact layer 842 adjacent to each other. When the width is 10 μm or less, light absorption in semiconductor layer 30 is easily reduced. Width A1 of first separation groove 121 is a distance between first end portion 841a and second end portion 842a in the optical axis direction.

Diffraction grating layer 33 includes a first region 33a and a second region 33b. First region 33a is a region in which constant-period diffraction gratings are formed in the optical axis direction. Second region 33b is a region where the diffraction gratings are not formed. First region 33a is positioned farther than second region 33b from optical amplifier portion 50 in the optical axis direction. In this case, first region 33a can be positioned far from a non-injection region 35a where electric current is not injected. Non-injection region 35a is a region of active layer 35, the region overlapping contact layer 84 in a plan view.

The boundary between first region 33a and second region 33b is positioned farther than first end portion 841a from optical amplifier portion 50 in the optical axis direction. In this case, first region 33a can be positioned far from non-injection region 35a. In non-injection region 35a, the efficiency is reduced by light absorption. By positioning first region 33a far away from non-injection region 35a, light passes through non-injection region 35a only once, and light absorption in non-injection region 35a can be reduced.

A distance A5 between the boundary between first region 33a and second region 33b and first end portion 841a in the optical axis direction may be 5 μm to 10 μm. When the distance is 5 μm or more, optical semiconductor element 5 is hardly affected by misalignment in manufacturing optical semiconductor element 5. When the distance is 10 μm or less, the characteristics of optical semiconductor element 5 are less likely to be affected.

Contact electrode 86 is provided on contact layer 84. Contact electrode 86 is, for example, an AuZn film or a TiPtAu film. Contact electrode 86 includes a contact electrode 861 and a contact electrode 862. Contact electrode 861 is provided in laser portion 40. Contact electrode 862 is provided in optical amplifier portion 50. Contact electrode 861 and contact electrode 862 are divided by a second separation groove 122. Contact electrode 861 and contact electrode 862 are insulated and separated from each other.

Contact electrode 861 has a third end portion 861a close to contact electrode 862 in the optical axis direction. Third end portion 861a is positioned farther than first end portion 841a from optical amplifier portion 50 in the optical axis direction. Contact electrode 862 has a fourth end portion 862a close to contact electrode 861 in the optical axis direction. Fourth end portion 862a is positioned farther than second end portion 842a from laser portion 40 in the optical axis direction. A width A2 of second separation groove 122 may be wider than width A1 of first separation groove 121. Width A2 of second separation groove 122 is a distance between third end portion 861a and fourth end portion 862a in the optical axis direction.

Electrically insulating film 91 is provided on contact electrode 86. Electrically insulating film 91 is, for example, a silicon oxide film, a silicon oxynitride film, or a silicon nitride film. Electrically insulating film 91 covers first separation groove 121 and second separation groove 122. Electrically insulating film 91 covers the upper surface of semiconductor layer 30 exposed by first separation groove 121, the upper surfaces and the side surfaces of contact layers 841 and 842 exposed by second separation groove 122, and the upper surfaces and the side surfaces of contact electrodes 861 and 862. In this case, moisture is prevented from entering semiconductor layer 30, contact layer 84, and contact electrode 86. Therefore, the moisture resistance of optical semiconductor element 5 is improved.

Underlying metal film 87 covers the upper surface of contact electrode 86 and a portion of the side surface and the upper surface of electrically insulating film 91. Underlying metal film 87 is, for example, a TiW film. Underlying metal film 87 includes an underlying metal film 871 and an underlying metal film 872. Underlying metal film 871 is provided in laser portion 40. Underlying metal film 872 is provided in optical amplifier portion 50. Underlying metal film 871 and underlying metal film 872 are divided each other by a third separation groove 123. Underlying metal film 871 and underlying metal film 872 are insulated and separated from each other. A width A3 of third separation groove 123 may be wider than width A1 of first separation groove 121. Width A3 of third separation groove 123 may be narrower than width A2 of second separation groove 122.

Upper electrode 71 is provided on underlying metal film 87. Upper electrode 71 covers underlying metal film 87. Upper electrode 71 is, for example, an Au electrode. Upper electrode 71 includes upper electrode 711 and upper electrode 712. Upper electrode 711 is provided in laser portion 40. Upper electrode 712 is provided in optical amplifier portion 50. Upper electrode 711 and upper electrode 712 are divided by a fourth separation groove 124. Upper electrode 711 and upper electrode 712 are insulated and separated from each other. A width A4 of fourth separation groove 124 may be the same as width A3 of third separation groove 123.

Lower electrode 72 is provided on second major surface 20B. Lower electrode 72 is in contact with substrate 20. Lower electrode 72 is, for example, an AuGe electrode or a TiPtAu electrode.

Although the separation structure between laser portion 40 and optical amplifier portion 50 adjacent to each other has been described in the example of FIG. 16, the separation structure between upper electrodes 712 adjacent to each other in optical amplifier portion 50 may be similar to the separation structure above. In this case, similarly, moisture is prevented from entering semiconductor layer 30, contact layer 84, and contact electrode 86. Therefore, the moisture resistance of optical semiconductor element 5 is improved.

### [Method of Manufacturing Optical Semiconductor Element According to Modification]

Referring to FIGS. 17 to 31, a method of manufacturing optical semiconductor element 5 according to a modification of the embodiment will be described. FIGS. 17 to 31 are cross-sectional views showing the method of manufacturing optical semiconductor element 5 according to the modification of the embodiment.

First, as shown in FIG. 17, substrate 20 having first major surface 20A and second major surface 20B is prepared. Next, diffraction grating layer 33 is formed on first major surface 20A. In the part included in laser portion 40, diffraction gratings are formed in diffraction grating layer 33, and in the part included in optical amplifier portion 50, the whole upper surface of substrate 20 is covered with diffraction grating layer 33. Thus, first region 33a and second region 33b are formed. Next, n-type cladding layer 34 is formed on diffraction grating layer 33. N-type cladding layer 34 covers diffraction grating layer 33.

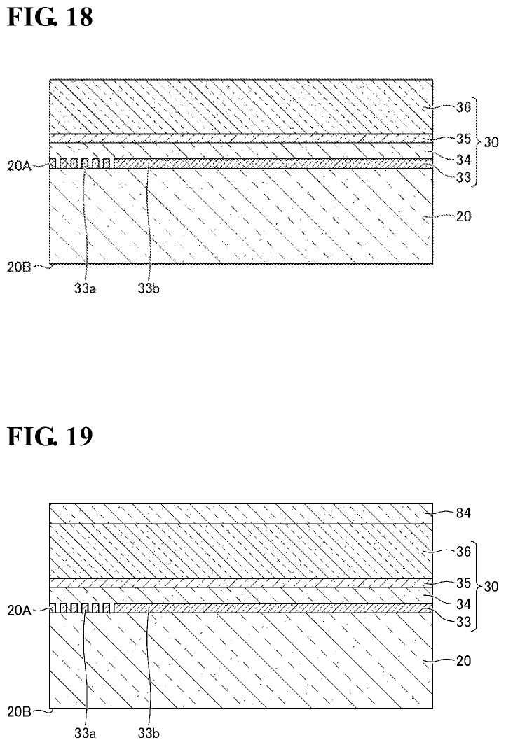

Next, as shown in FIG. 18, active layer 35 is formed on n-type cladding layer 34, and p-type cladding layer 36 is formed on active layer 35.

Next, as shown in FIG. 19, contact layer 84 is formed on p-type cladding layer 36.

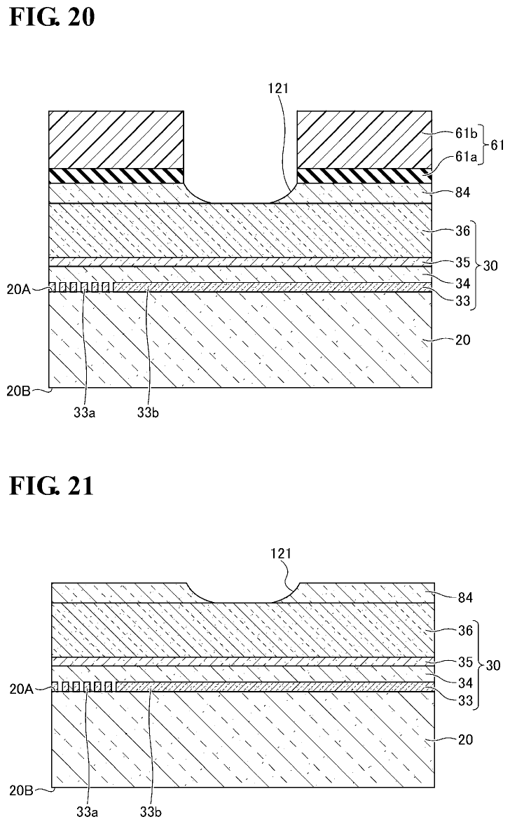

Next, as shown in FIG. 20, a mask 61 is formed on contact layer 84. Mask 61 has an opening on a region where first separation groove 121 is formed. Mask 61 is, for example, a laminated film of a silicon oxide film 61a and a resist film 61b. A silicon oxynitride film or a silicon nitride film may be used instead of silicon oxide film 61a. Next, contact layer 84 is wet-etched using mask 61 as an etching mask. As a result, first separation groove 121 is formed in contact layer 84. In the wet etching, contact layer 84 can be removed by a mixed solution of hydrochloric acid, sulfuric acid, hydrogen peroxide solution, and the like. In this case, the depth can be easily controlled by the etching selectivity of InP and GaInAsP. Specifically, the etching can be stopped at the upper surface of p-type cladding layer 36. In the wet etching, even when the surface has irregularities, contact layer 84 can be removed following the irregularities. Instead of wet etching, dry etching may be performed on contact layer 84. As the dry etching, for example, reactive ion etching (RIE) using tetrachlorosilane (SiCl₄) is performed. Next, as shown in FIG. 21, mask 61 is removed.

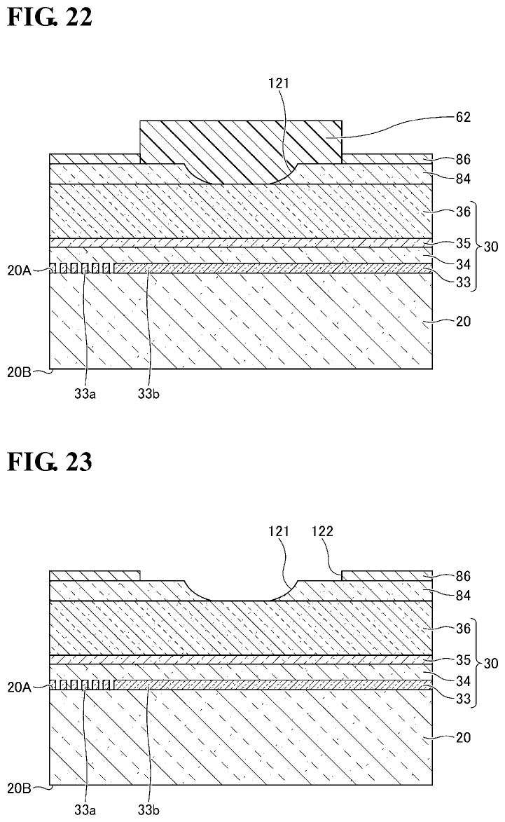

Next, as shown in FIG. 22, a mask 62 is formed. Mask 62 has an opening on a region where contact electrode 86 is to be formed. Mask 62 is, for example, a resist film. Next, contact electrode 86 is formed on contact layer 84 exposed from mask 62.

Next, as shown in FIG. 23, mask 62 is removed. Thus, second separation groove 122 is formed in contact electrode 86. Next, a trench (not shown) is formed. The trench can be formed by, for example, dry etching using an etching mask (not shown). As the dry etching, for example, RIE using SiCl₄ is performed.

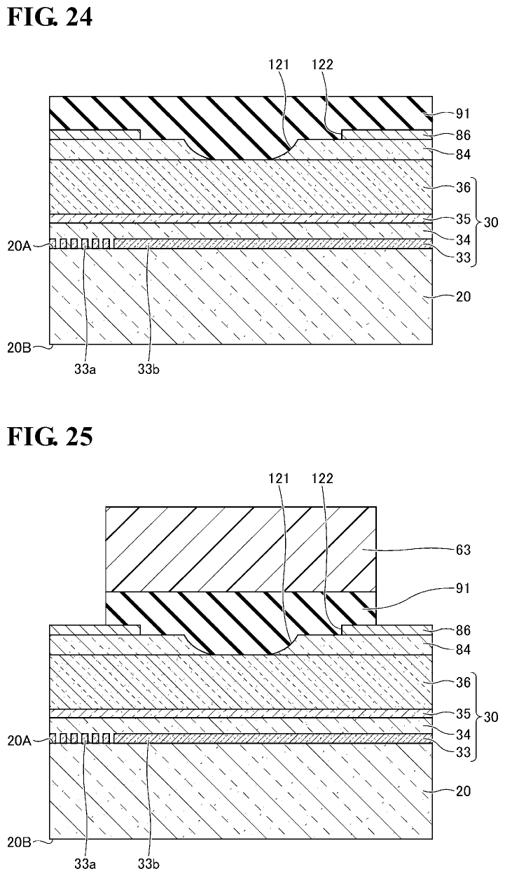

Next, as shown in FIG. 24, electrically insulating film 91 is formed to cover the upper surface of p-type cladding layer 36 exposed by first separation groove 121, the upper surface and the side surface of contact layer 84 exposed by second separation groove 122, and the upper surface and the side surface of contact electrode 86. Electrically insulating film 91 can be formed by, for example, a plasma enhanced-chemical vapor deposition (PE-CVD) method.

Next, as shown in FIG. 25, a mask 63 is formed on electrically insulating film 91. Mask 63 is formed on a region covering first separation groove 121 and second separation groove 122. Mask 63 is, for example, a resist film. Next, electrically insulating film 91 is etched using mask 63 as an etching mask.

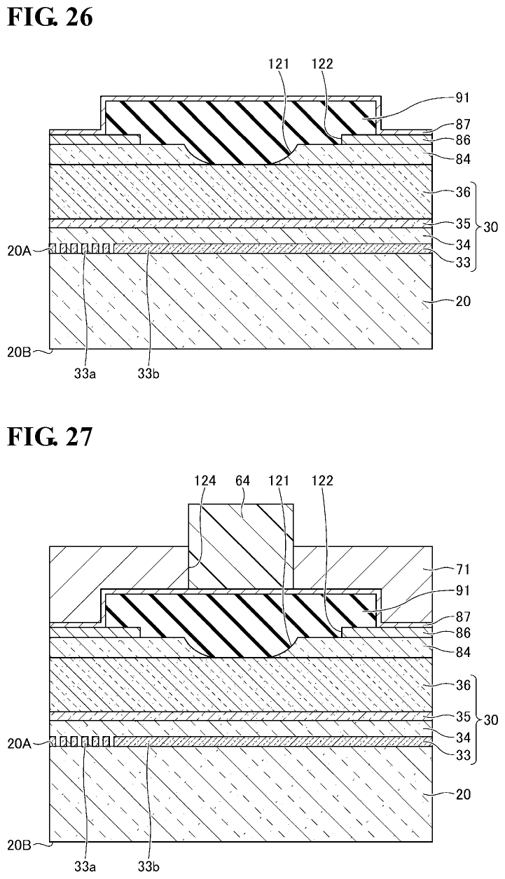

Next, as shown in FIG. 26, mask 63 is removed. Next, underlying metal film 87 is formed to cover the upper surface of contact electrode 86 and the upper surface and side surfaces of electrically insulating film 91. Underlying metal film 87 can be formed by, for example, a sputtering method.

Next, as shown in FIG. 27, a mask 64 is formed on underlying metal film 87. Mask 64 has an opening on a region where upper electrode 71 is formed. Mask 64 is, for example, a resist film. Next, upper electrode 71 is formed on underlying metal film 87 exposed from mask 64. Upper electrode 71 can be formed by, for example, a plating method.

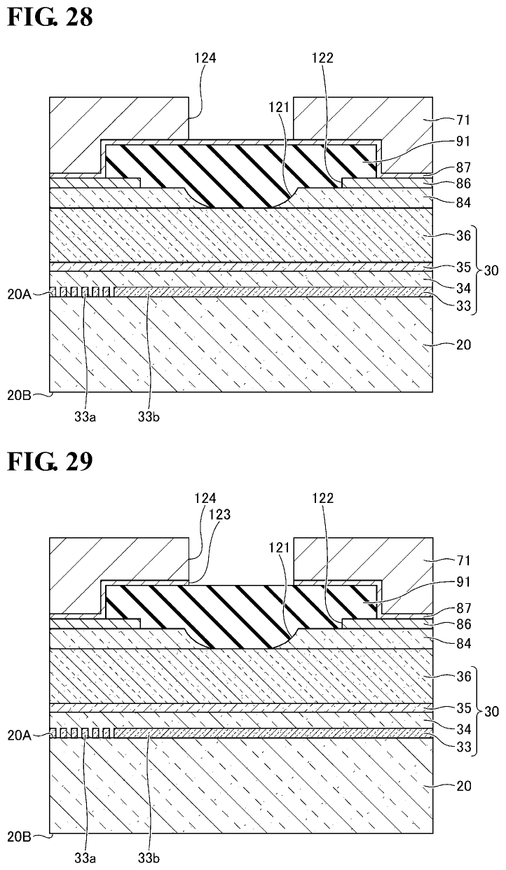

Next, as shown in FIG. 28, mask 64 is removed. Thus, fourth separation groove 124 is formed in upper electrode 71.

Next, as shown in FIG. 29, underlying metal film 87 exposed from fourth separation groove 124 is removed. Thus, third separation groove 123 is formed in underlying metal film 87. Underlying metal film 87 can be removed by, for example, dry etching. As the dry etching, for example, ion milling or RIE is performed. In this case, side etching is less likely to occur in upper electrode 71. That is, the side surface of fourth separation groove 124 is not easily etched. Underlying metal film 87 exposed from fourth separation groove 124 may be removed by wet etching instead of dry etching. Underlying metal film 87 can be removed by using, for example, hydrofluoric acid (HF).

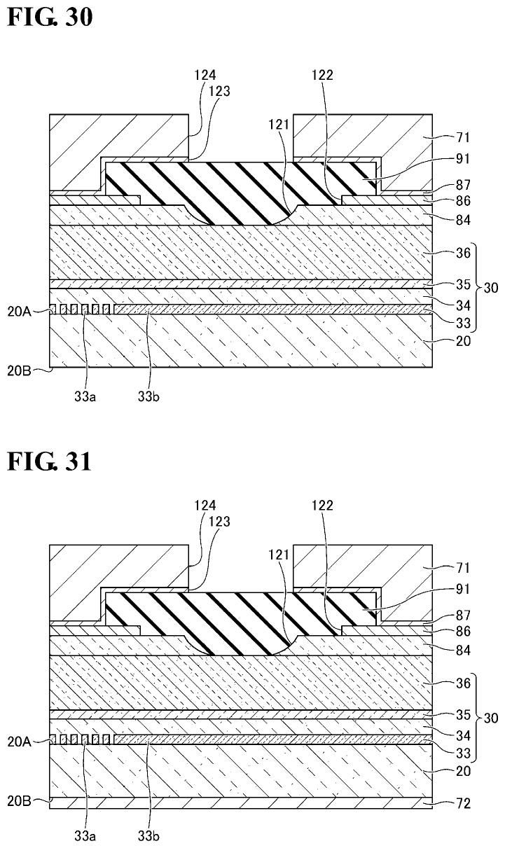

Next, as shown in FIG. 30, substrate 20 is polished from second major surface 20B.

Next, as shown in FIG. 31, lower electrode 72 is formed under second major surface 20B so as to be in contact with substrate 20.

In this way, optical semiconductor element 5 according to the modification of the embodiment can be manufactured.

Although the embodiments have been described in detail, the present invention is not limited to the specific embodiments, and various modifications and changes can be made within the scope described in the claims.

What is claimed is:

1. An optical semiconductor device comprising:
an optical amplifier portion configured to amplify a laser beam;
a plurality of wiring pads for causing electric current to flow to the optical amplifier portion; and
bonding wires,
wherein the optical amplifier portion includes a plurality of electrodes divided from each other in an optical axis direction,
wherein the number of the plurality of electrodes is greater than the number of the plurality of wiring pads, and
wherein the bonding wires each connect a corresponding one of the plurality of electrodes to one of the plurality of wiring pads.

2. The optical semiconductor device according to claim 1,
wherein the plurality of electrodes are divided from each other at equal intervals.

3. The optical semiconductor device according to claim 1,
wherein lengths of the plurality of electrodes in the optical axis direction are identical to each other.

4. The optical semiconductor device according to claim 1, comprising:
a laser portion integrated with the optical amplifier portion and configured to emit the laser beam.

5. The optical semiconductor device according to claim 4,
wherein the laser portion is of a distributed feedback type.

6. The optical semiconductor device according to claim 4,
wherein the laser portion includes a diffraction grating layer and a contact layer provided on the diffraction grating layer,
wherein the diffraction grating layer includes a first region in which constant-period diffraction gratings are formed in the optical axis direction and a second region in which the diffraction gratings are not formed, and
wherein the first region is positioned farther than the second region from the optical amplifier portion in the optical axis direction.

7. The optical semiconductor device according to claim 6,
wherein the contact layer includes a first end portion close to the optical amplifier portion in the optical axis direction, and
wherein a boundary between the first region and the second region is positioned farther than the first end portion from the optical amplifier portion in the optical axis direction.

8. The optical semiconductor device according to claim 7,
wherein a distance between the boundary and the first end portion in the optical axis direction is 5 μm to 10 μm.

9. The optical semiconductor device according to claim 4,
wherein the laser portion and the optical amplifier portion each include
a semiconductor layer,
a contact layer provided on the semiconductor layer,
a contact electrode provided on the contact layer, and
an electrically insulating film provided on the contact electrode,
wherein the contact layer and the contact electrode are divided between the laser portion and the optical amplifier portion by a separation groove, and
wherein the separation groove is covered by the electrically insulating film.

10. The optical semiconductor device according to claim 1,
wherein the optical amplifier portion includes
a semiconductor layer,
a contact layer provided on the semiconductor layer,
a contact electrode provided on the contact layer, and
an electrically insulating film provided on the contact electrode,
wherein the contact layer and the contact electrode are divided in the optical axis direction into a plurality of contact layers and a plurality of contact electrodes by a separation groove, and
wherein the separation groove is covered by the electrically insulating film.

11. The optical semiconductor device according to claim 9,
wherein a width of the separation groove at an interface between the semiconductor layer and the contact layer is 5 μm to 10 μm.

12. A method of manufacturing an optical semiconductor device, the method comprising:
preparing an optical semiconductor element, the optical semiconductor element including a laser portion configured to emit a laser beam and an optical amplifier portion configured to amplify the laser beam;
preparing a submount provided with a plurality of wiring pads for causing electric current to flow to the optical amplifier portion; and
mounting the optical semiconductor element on the submount,
wherein the optical amplifier portion includes a plurality of electrodes divided from each other in an optical axis direction,
wherein the number of the plurality of electrodes is greater than the number of the plurality of wiring pads, and
wherein the mounting includes connecting each of the plurality of electrodes by a corresponding one of bonding wires to one of the plurality of wiring pads.

13. The method of manufacturing the optical semiconductor device according to claim 12,
wherein the mounting includes determining, in accordance with a target value of an optical output of the optical semiconductor element, positions to which the bonding wires are connected.
